(19) United States
(12) Patent Application Publication
(10) Pub. No.: US 2026/0047087 A1
(43) Pub. Date: Feb. 12, 2026

(54) NON-VOLATILE MEMORY BIT CELL

(71) Applicant: SEMICONDUCTOR COMPONENTS INDUSTRIES, LLC, Scottsdale, AZ (US)

(72) Inventors: Gang LIU, Camas, WA (US); Santosh MENON, Portland, OR (US)

(73) Assignee: SEMICONDUCTOR COMPONENTS INDUSTRIES, LLC, Scottsdale, AZ (US)

(21) Appl. No.: 18/800,694

(22) Filed: Aug. 12, 2024

(51) Int. Cl. H10B 41/30; G11C 16/14; H01L 29/423; H01L 29/66; H01L 29/788; H10B 41/10

(52) U.S. Cl. CPC H10B 41/30; G11C 16/14; H10B 41/10; H10D 30/0411; H10D 30/68; H10D 30/6891

(57) ABSTRACT

A non-volatile memory (NVM) bit cell is disclosed. The NVM bit cell includes a first well region and a second well region. The NVM bit cell also includes an isolation trench between the first well region and the second well region. The isolation trench has a trench depth that is greater than a well depth of the first well region and the second well region. The NVM bit cell further includes a control gate formed in the first well region. In addition, the NVM bit cell includes a state transistor formed in the second well region. The state transistor has a floating-gate terminal coupled to a floating terminal of the control gate. The NVM bit cell also includes an access transistor formed in the second well region and coupled in series with the state transistor.

### TECHNICAL FIELD

The disclosure relates generally to integrated circuit technology, and particularly to a design and method of manufacturing a non-volatile memory device.

### BACKGROUND

Integrated circuits may be fabricated to include both a data processing unit, such as a central processing unit or a graphics processing unit, as well as a memory block that may be used to store data for use by the data processing unit. In some configurations, the memory block may include a non-volatile memory (NVM) such as an electrically erasable programmable read only memory (EEPROM).

Conventional technologies for including non-volatile memory on the same complementary metal-oxide semiconductor (CMOS) integrated circuit as a data processing unit have leveraged the gate oxide of the CMOS process to instantiate a logic-based, single-poly, floating gate EEPROM. The inventors of embodiments of the present disclosure have recognized that such embedded single-poly EEPROM cells typically require control gate and floating gate transistors separate from an access transistor and a state transistor, as well as isolation thereof. Relatedly, the inventors of embodiments of the present disclosure have also recognized that the footprint of such embedded single-poly EEPROM cells is typically large, thus consuming significant area of the semiconductor die. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a block diagram of an integrated circuit in accordance with embodiments of the present disclosure.

FIG. 2 illustrates a schematic diagram of a non-volatile memory bit cell in accordance with embodiments of the present disclosure.

FIG. 3 is a chart illustrating operating conditions of a non-volatile memory bit cell in accordance with embodiments of the present disclosure.

FIG. 4 illustrates a top view of semiconductor process areas for a non-volatile memory bit cell in accordance with embodiments of the present disclosure.

FIG. 5A illustrates a cross-section view of a non-volatile memory bit cell in accordance with embodiments of the present disclosure.

FIG. 5B illustrates a cross-section view of a non-volatile memory bit cell in accordance with embodiments of the present disclosure.

FIG. 6 is a chart illustrating operating conditions of a non-volatile memory bit cell in accordance with embodiments of the present disclosure.

FIG. 7 illustrates a method for manufacturing an non-volatile memory bit cell in accordance with embodiments of the present disclosure.

### DETAILED DESCRIPTION

Details of one or more embodiments are set forth in the description below and the accompanying drawings. Other features will be apparent from the description, drawings, and from the claims.

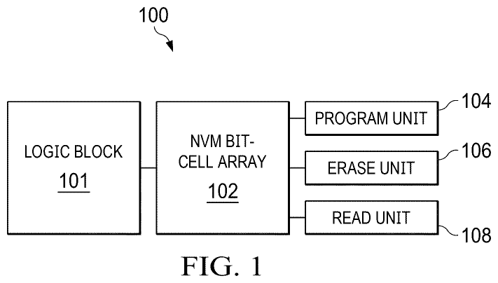

FIG. 1 illustrates a block diagram of integrated circuit 100 in accordance with embodiments of the present disclosure. Integrated circuit 100 may include logic block 101, non-volatile memory (NVM) bit-cell array 102, program unit 104, erase unit 106, and read unit 108. Logic block 101 may include a data processing unit, such as a central processing unit or a graphics processing unit. Logic block 101 may be coupled to NVM bit-cell array 102 and may utilize NVM bit-cell array 102 to store information that may be used in one or more data processing functions.

Program unit 104, erase unit 106, and read unit 108 may be configured to provide the respective voltages to NVM bit-cell array 102 for programming, erasing, and reading bit cells within NVM bit-cell array 102. As shown in FIG. 1, program unit 104, erase unit 106, and read unit 108 may in some embodiments be implemented as separate units. In other embodiments, program unit 104, erase unit 106, and read unit 108 may be implemented together in a single circuit with, for example, a charge pump and one or more voltage dividers that may collectively be used to generate the different respective voltages used for programming, erasing, and reading one or more bit cells of NVM bit-cell array 102.

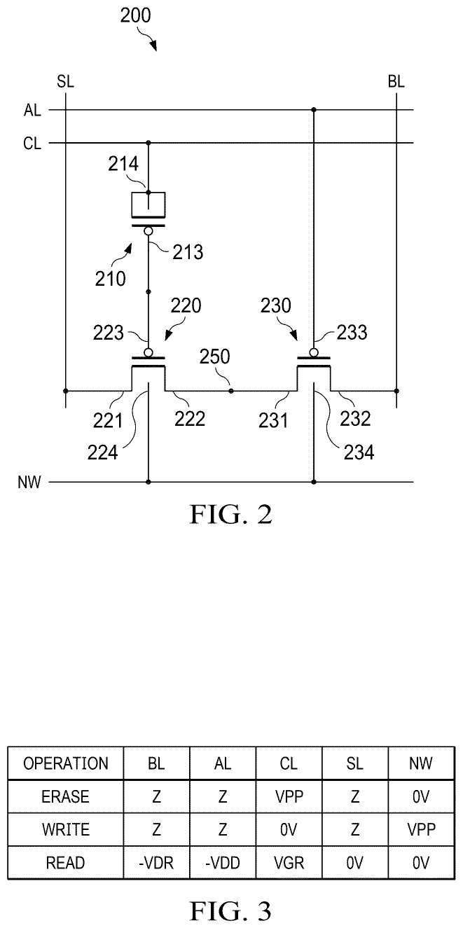

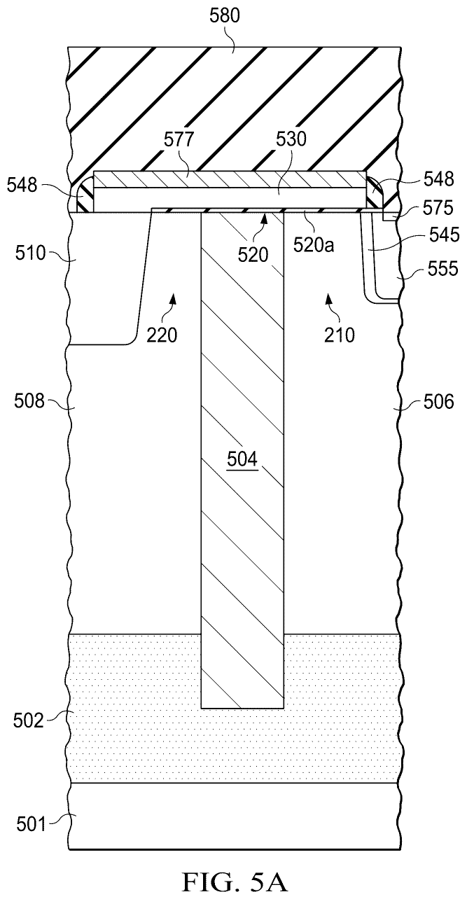

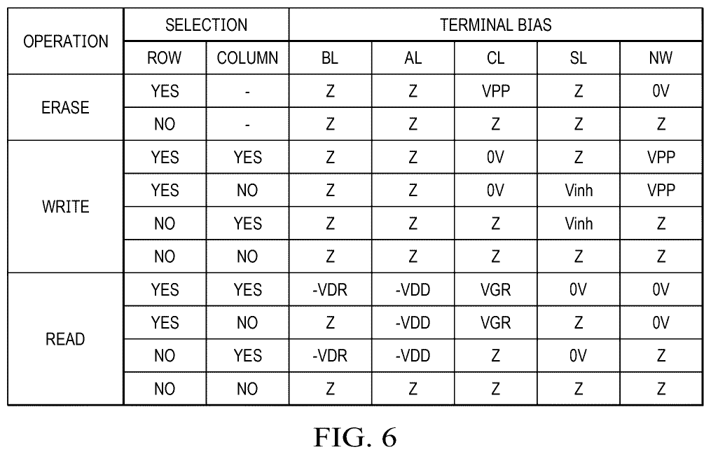

FIG. 2 illustrates a schematic diagram of non-volatile memory (NVM) bit cell 200 in accordance with embodiments of the present disclosure. NVM bit cell 200 may include control gate 210, state transistor 220, and access transistor 230. NVM bit cell 200 may also be connected to various input and output lines used to program, erase, and read the status of NVM bit cell 200. For example, as described in further detail below, various terminals of NVM bit cell 200 may be coupled to the access line AL, the control line CL, the source line SL, the bit line BL, and the n-well line NW. As also described below with reference to FIGS. 4 and 6, NVM bit cell 200 may represent one bit cell in an array of bit cells with multiple rows and multiple columns formed of different instances of NVM bit cell 200. Thus, as described in further detail below, one instance of NVM bit cell 200 may share connections to one or more of the access line AL, the control line CL, the source line SL, the bit line BL, and the n-well line NW with other instances of NVM bit cell 200.

Control gate 210 may include floating terminal 213 and control terminal 214. Control terminal 214 may be coupled to the control line CL. Floating terminal 213 may be coupled to floating-gate terminal 223 of state transistor 220. As described in further detail below, control gate 210 may be formed in a first well region, for example, a first n-well region. Control gate 210 may include a capacitance from a first well (for example, a first n-well) that forms control terminal 214, across a control-gate tunnel oxide layer, and to a layer of polysilicon (also referred to herein as a layer of “poly”) that forms floating terminal 213. The poly layer may be a shared poly layer that may form both floating terminal 213 of control gate 210 and floating-gate terminal 223 of state transistor 220.

State transistor 220 may include source terminal 221 coupled to the source line SL and drain terminal 222 coupled to intermediate node 250. State transistor 220 may also include floating-gate terminal 223 coupled to floating terminal 213 of control gate 210. The gate of state transistor 220 may be implemented with a state-transistor tunnel oxide layer located under the shared poly layer forming both floating terminal 213 of control gate 210 and floating-gate terminal 223 of state transistor 220. As described in further detail below, state transistor 220 may be formed in a second well region, for example, a second n-well region. In embodiments where the second well region is a second n-well region, state transistor 220 may be a p-type metal-oxide semiconductor field effect transistor (“P-type MOSFET” or “PMOS transistor”) and may thus be referred to as a PMOS state transistor. Further, in such embodiments, state transistor 220 may include body terminal 224 coupled to the n-well line NW.

Access transistor 230 may be coupled in series with state transistor 220. For example, access transistor 230 may include source terminal 231 coupled to drain terminal 222 of state transistor 220 at intermediate node 250. Access transistor 230 may also include drain terminal 232 coupled to the bit line BL and gate terminal 233 coupled to the access line AL. Similar to state transistor 220, the gate of access transistor 230 may be implemented with a tunnel oxide layer located under a poly layer forming gate terminal 233. As described in further detail below, access transistor 230 may be formed in a second well region, for example, a second n-well region, along with state transistor 220. In embodiments where the second well region is a second n-well region, access transistor 230 may be a PMOS transistor, and may thus be referred to as a PMOS access transistor. Further, in such embodiments, access transistor 230 may include body terminal 234 coupled to the n-well line NW.

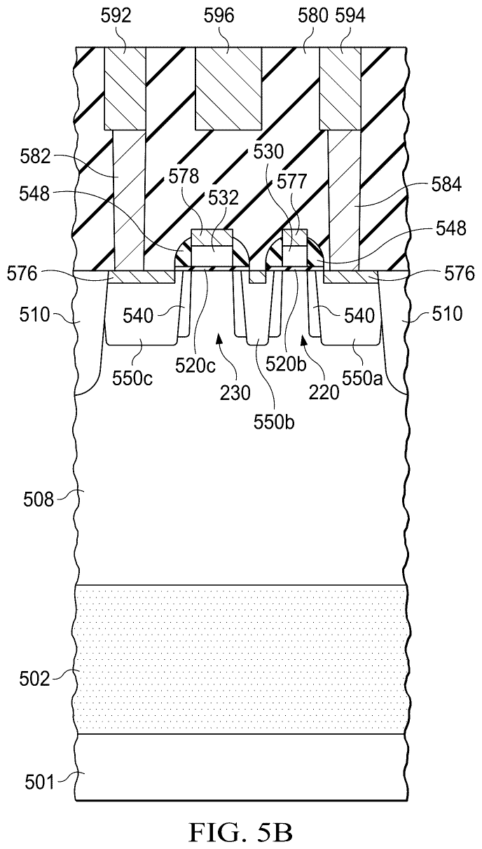

As described in further detail below with reference to FIGS. 5A and 5B, control gate 210 may be formed in a first well region corresponding to first n-well 506. First n-well 506 may thus serve as control terminal 214 of control gate 210. Moreover, control gate 210 may include control-gate tunnel oxide layer 520a separating first n-well 506, which may form control terminal 214, and shared poly layer 530, which may form floating terminal 213 of control gate 210 and floating-gate terminal 223 of state transistor 220. Further, state transistor 220 and access transistor 230 may be formed in a second well region corresponding to second n-well 508. Second n-well 508 may thus serve as body terminal 224 of state transistor 220 and as body terminal 234 of access transistor 230. In addition, state transistor 220 may include state-transistor tunnel oxide layer 520b separating second n-well 508, which may form body terminal 224, and shared poly layer 530, which may form floating-gate terminal 223 of state transistor 220 and floating terminal 213 of control gate 210. In some embodiments, control-gate tunnel oxide layer 520a and state-transistor tunnel oxide layer 520b, as well as access-transistor tunnel oxide layer 520c, may be formed by the same tunnel oxide growth process, and may represent different patterned portions of tunnel oxide layer 520.

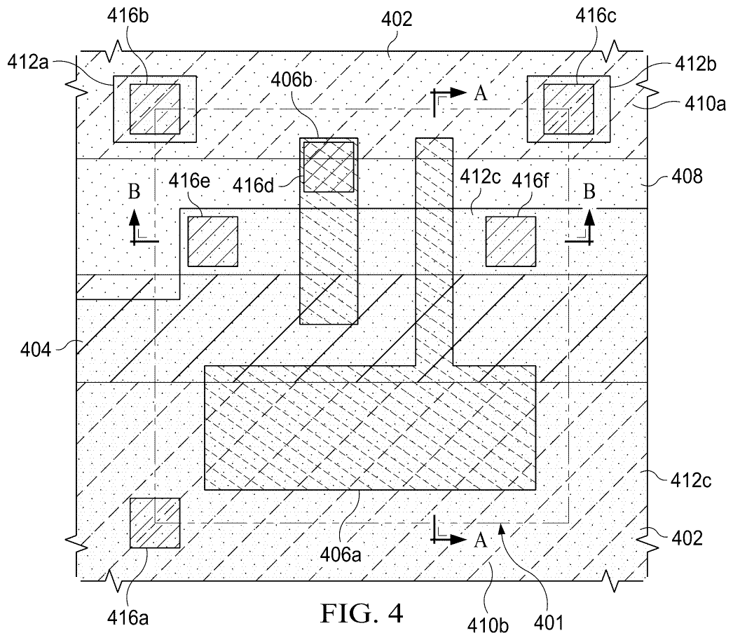

As also described below with reference to FIGS. 4, 5A, and 5B, first n-well 506 (forming control terminal 214 of control gate 210 coupled to the control line CL) may be separated from second n-well 508 (forming body terminal 224 of state transistor 220 coupled to the n-well line NW) by isolation trench 504. Thus, as described below with reference to FIG. 3, the voltages of the control line CL and the n-well line NW may be utilized to write and erase the state of NVM bit cell 200.

FIG. 3 is a chart illustrating the operating conditions of NVM bit cell 200 in accordance with embodiments of the present disclosure. As described directly below, state transistor 220 and control gate 210 may be collectively configured to utilize Fowler-Nordheim tunneling for an erase operation and for a write operation.

To perform an erase operation, the bit line BL, the access line AL, and the source line SL, may all be set to high impedance, as represented by “Z” in FIG. 3. For example, any other external connections to BL, AL, and SL may be turned off such that there is an open-circuit high-impedance condition on each of the BL, AL, and SL lines. Further, a program voltage VPP may be applied to the control line CL and a nominal voltage, of for example, 0 volts may be applied to the n-well line NW. The program voltage VPP may be, for example, 10 volts, or any other voltage higher than the voltage applied to the n-well line NW suitable to induce Fowler-Nordheim tunneling as described directly below.

With, for example, a VPP of 10 volts applied to the control line CL, and a nominal voltage of 0 volts applied to the n-well line NW, the large voltage drop may cause electron tunneling across the state-transistor tunnel oxide layer 520b of state transistor 220 and the control-gate tunnel oxide layer 520a of control gate 210. As described below with reference to FIGS. 4, 5A, and 5B, a first gate capacitance across control-gate tunnel oxide layer 520a of control gate 210, from first n-well 506 forming control terminal 214 to shared poly layer 530 forming floating terminal 213, may be larger than a second gate capacitance across state-transistor tunnel oxide layer 520b of state transistor 220, from second n-well 508 forming body terminal 224 to shared poly layer 530 forming floating-gate terminal 223. Accordingly, the first gate capacitance of control gate 210 may have a larger influence than the second gate capacitance of state transistor 220 on the amount of charge on floating terminal 213 of control gate 210 and floating-gate terminal 223 of state transistor 220, and the resulting voltage during an erase operation. For example, in embodiments where control gate 210 has a first gate capacitance four times larger than a second gate capacitance of state transistor 220, applying a VPP of 10 volts to the control line CL and a nominal voltage of 0 volts to the n-well line NW, may provide a charge accumulation at shared poly layer 530, which forms floating terminal 213 and floating-gate terminal 223, resulting in an erase-state voltage of approximately 8 volts. When the erase-operation voltages are removed from the control line CL and the n-well line NW, the charge accumulated at shared poly layer 530 may remain and may thus be used for detecting the erase-state during a subsequent read operation.

To perform an write operation, the bit line BL, the access line AL, and the source line SL, may all be set to high impedance, as represented by “Z” in FIG. 3. For example, any other external connections to BL, AL, and SL may be turned off such that there is an open-circuit high-impedance condition on each of the BL, AL, and SL lines. Further, a program voltage VPP may be applied to the n-well line NW and a nominal voltage, of for example, 0 volts may be applied to the control line CL. The program voltage VPP may be, for example, 10 volts, or any other voltage higher than the voltage applied to the control line CL suitable to induce Fowler-Nordheim tunneling as described directly below.

With, for example, a VPP of 10 volts applied to the n-well line NW, and a nominal voltage of 0 volts applied to the control line CL, the large voltage drop may cause electron tunneling across control-gate tunnel oxide layer 520a of control gate 210 and state-transistor tunnel oxide layer 520b of state transistor 220. As described below with reference to FIGS. 4, 5A, and 5B, the first gate capacitance across control-gate tunnel oxide layer 520a of control gate 210 may be larger than the second gate capacitance across the state-transistor tunnel oxide layer 520b of state transistor 220. Accordingly, the first gate capacitance of control gate 210 may have a larger influence than the second gate capacitance of state transistor 220 on the amount of charge and the resulting voltage during a write operation. For example, in embodiments where control gate 210 has a first gate capacitance four times larger than a second gate capacitance of state transistor 220, applying a VPP of 10 volts to the n-well line NW and a nominal voltage of 0 volts to the control line CL, may provide a charge accumulation at shared poly layer 530, which forms floating terminal 213 of control gate 210 and floating-gate terminal 223 of state transistor 220, resulting in a write-state voltage of approximately 2 volts. When the write-operation voltages are removed from the control line CL and the n-well line NW, the charge accumulated at shared poly layer 530 may remain and may thus be used for detecting the write-state during a subsequent read operation.

After an erase operation or a write operation, a read operation may be performed by turning on access transistor 230, applying a drain-to-source voltage across state transistor 220, and monitoring the current conducted by state transistor 220. The current conducted by state transistor 220 for a given drain-to-source source voltage may depend on the charge accumulation remaining at shared poly layer 530 forming floating terminal 213 and floating-gate terminal 223 and may thus indicate whether NVM bit cell 200 is in an erase-state or a write-state.

For example, during a read operation, a nominal voltage of zero volts may be applied to the source line SL and the n-well line NW. A negative supply voltage −VDD may be applied to the access line AL. In some embodiments, the −VDD voltage may be for example −1.8 volts, or any other negative voltage suitable to turn on access transistor 230 and to drive access transistor 230 in saturation. Further, a gate-read voltage VGR may be applied to the control line. The gate-read voltage VGR, may in combination with the charge accumulated on the shared poly layer 530 forming floating terminal 213 and floating-gate terminal 223, provide a bias voltage to floating-gate terminal 223 of state transistor 220. For example, the gate-read voltage VGR may be placed at any suitable baseline voltage such that state transistor 220 may be biased in an on-state if the NVM bit cell 200 was placed in a write-state before the read operation, and may be biased in an off-state if the NVM bit cell 200 was placed in an erase-state before the read operation. Further, a negative drive voltage (−VDR) may be applied to bit line BL. The −VDR voltage may be utilized to apply a drain-to-source voltage across state transistor 220. In some embodiments, −VDR may be equal to a −VDD voltage of −1.8V for example. With the negative −VDR voltage applied to the bit line BL, a nominal voltage of for example 0 volts applied to the source line SL, and access transistor 230 driven in an on-state, the amount of current conducted at the bit line BL may depend on the biasing at the floating-gate terminal 223 of state transistor 220. Thus, the amount of current conducted at the bit line BL may indicate whether NVM bit cell 200 was last placed in an erase-state or a write-state prior to the read operation.

Although the example voltage values for the read operation shown in FIG. 3 lists a nominal voltage of 0V for the source line SL and n-well line NW and negative voltages for bit BL and access line AL, alternative voltage values with the same relative difference may be utilized to achieve the same read operation. For example, the bit line BL and access line AL may be placed at a nominal voltage of zero volts while the source line SL and n-well line NW are placed at a positive voltage of, for example, +1.8 volts. In such embodiments, the gate-read voltage VGR may be similarly adjusted such that state transistor 220 may be biased in an on-state if the NVM bit cell 200 was placed in a write-state before the read operation, and may be biased in an off-state if the NVM bit cell 200 was placed in an erase-state before the read operation.

Further, although the above embodiments refer to tunnelling during the erase operation and the write operation such that state transistor 220 may be placed in an on-state during a read operation following a write operation, and may be placed in an off-state during a read operation following an erase operation, the designation of “WRITE” and “ERASE” may be switched. For example, in alternate embodiments, the designation of the “ERASE” and “WRITE” operations in FIG. 3 may be switched with each other such that state transistor 220 may be placed in an on-state during a read operation following an erase operation and may be placed in an off-state during a read operation following a write operation.

FIG. 4 illustrates a top view of semiconductor process areas for a non-volatile memory (NVM) bit cell in accordance with embodiments of the present disclosure. Certain semiconductor process areas are described with reference to the top view of FIG. 4 and may be utilized to manufacture the elements of an NVM bit cell, such as NVM bit cell 200 described above with reference to FIG. 2, including control gate 210, state transistor 220, and access transistor 230.

As shown in FIG. 4, the semiconductor process areas may include n-well area 402. In initial semiconductor processing steps, n-well area 402 may be utilized to create an n-well across the entire bit cell area. The semiconductor process areas may also include isolation-trench area 404. As described in further detail below with reference to FIG. 5A, the resulting isolation trench 504 may have a trench depth that is greater than the depth of the n-well formed in n-well area 402. The isolation trench may thus separate the n-well initially formed in n-well area 402 into a first n-well and a second n-well. As described in further detail below with reference to FIGS. 5A and 5B, the portion of the n-well on a first side of the isolation trench (the portion below isolation-trench area 404 in FIG. 4) may form first n-well 506 of the first n-well region in which control gate 210 may be formed. The portion of the n-well on the opposing side of the isolation trench (the portion above isolation-trench area 404 in FIG. 4) may form second n-well 508 of the second n-well region in which state transistor 220 and access transistor 230 may be formed.

As shown in FIG. 4, the semiconductor process areas may include two poly areas 406a and 406b. Poly area 406a may be utilized to form the shared poly layer that forms floating terminal 213 of control gate 210 and floating-gate terminal 223 of state transistor 220. Poly area 406b may be utilized to form the poly layer that forms gate terminal 233 of access transistor.

The semiconductor process areas may further include p-doping area 408 and n-doping areas 410a and 410b. P-doping area 408 may be utilized to add p-type doping to underlying poly areas and to underlying n-well areas. As described below with reference to FIG. 5B, this p-doping area may be utilized to form the p-type source and drain regions of state transistor 220 and access transistor 230 within second n-well 508. N-doping areas 410a and 410b may be utilized to add n-type doping to underlying poly areas and to add further n-type doping to underlying n-well areas.

The semiconductor process areas may further include active areas 412a, 412b, and 412c. Active areas 412a, 412b, and 412c may be utilized to form a silicide on the active areas of the bit cell, which may improve the electrical conductivity of contacts to underlying regions. Further, active areas 412a, 412b, and 412c, may also be utilized to delineate areas of shallow trench isolation. For example, in some embodiments, any area outside of active areas 412a, 412b, and 412c and isolation-trench area 404, may include shallow trench isolation. In some embodiments, the resulting shallow-trench isolation regions may have a trench depth less than that of the isolation trench corresponding to isolation-trench area 404.

The semiconductor process areas may further include contact areas 416a, 416b, 416c, 416d, 416e, and 416f. Contact areas 416a, 416b, 416c, 416d, 416e, and 416f may be utilized to form contacts from underlying active or poly areas to above metal layers. For example, contact area 416a may be utilized to form a contact that may couple the first n-well forming control terminal 214 of control gate 210 to the control line CL. In addition, contact areas 416b and 416c may be utilized to form contacts that may couple the second n-well forming body terminal 224 of state transistor 220 and body terminal 234 of access transistor 230 to the n-well line NW. Further, contact area 416d may be utilized to form a contact that may couple the poly region forming gate terminal 233 of access transistor 230 to the access line AL. Contact area 416e may be utilized to form a contact that may couple drain terminal 232 of access transistor 230 to the bit line BL. And contact area 416f may be utilized to form a contact that may couple source terminal 221 of state transistor 220 to the source line SL.

FIG. 5A and FIG. 5B illustrate cross-section views of non-volatile memory (NVM) bit cell 200 in accordance with embodiments of the present disclosure. FIG. 5A illustrates a cross-section view of NVM bit cell 200, corresponding to the cutline “A” of the semiconductor process areas in FIG. 4. Additionally, FIG. 5B illustrates a cross-section view of NVM bit cell 200 corresponding to the cutline “B”of the semiconductor process areas in FIG. 4.

NVM bit cell 200 may be formed on a semiconductor substrate including an epitaxial layer. For example, semiconductor substrate 501 may be provided. Epitaxial layer 502 may be provided on semiconductor substrate 501 or separately grown on semiconductor substrate 501. In some embodiments, semiconductor substrate 501 may be a p-type semiconductor substrate and epitaxial layer 502 may be a p-type epitaxial layer.

Isolation trench 504 may be formed in the epitaxial layer 502. And as described above with reference to FIG. 4, n-type doping may be applied to epitaxial layer 502 to create first n-well 506 on one side of isolation trench 504 and second n-well 508 on the opposing side of isolation trench 504. For the purposes of the present disclosure, the area including first n-well 506 and the space above first n-well 506 may be referred to as the first well region or the first n-well region. Likewise, for the purposes of the present disclosure, the area including second n-well 508 and the space above second n-well 508 may be referred to as the second well region or second n-well region.

To separate and provide electrical isolation between first n-well 506 and second n-well 508, isolation trench 504 may be located between the first well region including first n-well 506 and the second well region including second n-well 508. Further, isolation trench 504 may have a trench depth that is greater than a well depth of the first well region and the second well region. For example, isolation trench 504 may have a trench depth that is greater than the well depth of first n-well 506 and second n-well 508. In some embodiments, the trench depth of isolation trench 504 may be less than the depth of epitaxial layer 502, but greater than the well depth of first n-well 506 and second n-well 508. In other embodiments, the depth of isolation trench 504 may extend down to the same depth of epitaxial layer 502 or further beyond the depth of epitaxial layer 502 and into semiconductor substrate 501.

As shown in FIGS. 5A and 5B, NVM bit cell 200 may also include regions of shallow trench 510. As described above, regions of shallow trench 510 may be included in areas outside of the active areas corresponding to active areas 412a, 412b, and 412c shown in the top view of FIG. 4.

In some embodiments, tunnel oxide layer 520 may be grown over exposed areas of first n-well 506 and second n-well 508. As described above with reference to FIG. 4, control gate 210 may be formed in the first well region corresponding to first n-well 506. Thus, as shown in FIG. 5A, the portion of tunnel oxide layer 520 formed over first n-well 506 may thus form control-gate tunnel oxide layer 520a. As also described above with reference to FIG. 4, state transistor 220 and access transistor 230 may be formed in the second well region corresponding to second n-well 508. For the purposes of the present disclosure, the portion of tunnel oxide layer 520 included within state transistor 220 may also be referred to as the state-transistor tunnel oxide layer 520b, as shown in FIG. 5B. Moreover, for the purposes of the present disclosure, the portion of tunnel oxide layer 520 included within access transistor 230 may be referred to as the access-transistor tunnel oxide layer 520c.

After tunnel oxide layer 520 is grown, a single layer of poly may be deposited and patterned. As shown in FIGS. 5A and 5B, the patterned poly may form shared poly layer 530 as well as poly layer 532. Shared poly layer 530 may correspond to poly area 406a shown in FIG. 4, and poly layer 532 may correspond to poly area 406b shown in FIG. 4. As shown in FIG. 5A, shared poly layer 530 may extend across isolation trench 504 and over first n-well 506 and second n-well 508. Shared poly layer 530 may form both the floating terminal 213 of control gate 210 and floating-gate terminal 223 of state transistor 220. And as shown in FIG. 5B, poly layer 532 may be located over the portion of second n-well 508 corresponding to access transistor 230. Poly layer 532 may form gate terminal 233 of access transistor 230, which as described above with reference to FIG. 2 may be coupled to the access line AL. Because a single poly layer may be deposited and patterned to form shared poly layer 530 for control gate 210 and state transistor 220 as well as poly layer 532 for access transistor 230, NVM bit cell 200 may also be referred to as a single-poly NVM bit cell.

After the single layer of poly is deposited and patterned to form shared poly layer 530 and poly layer 532, active areas of NVM bit cell 200 may be doped. A light p-type doping may be utilized to generate lightly-doped p-regions 540 within the second n-well 508. Further, a light n-type doping may be utilized to generate lightly doped n-regions 545 within first n-well 506. Spacers 548 may then be formed to the sides of shared poly layer 530 and poly layer 532. In some embodiments, spacers 548 may be implemented with or include an oxide that may be either grown or deposited and patterned.

After spacers 548 are formed, a heavy n-type doping may be utilized to generate heavy-doped n-region 555 shown in FIG. 5A. Although the coupling between first n-well 506 (which forms the control terminal 214 of control gate 210) and the control line CL is not shown in the cross-section slice of FIG. 5A, heavy-doped n-region 555 together with silicide 575 and a contact through thick oxide 580 may be utilized to couple first n-well 506 to a conductive metal line 596 coupled to the control line CL.

Further, a heavy p-type doping may be utilized to generate heavy-doped p-regions 550a, 550b, and 550c shown in FIG. 5B. Heavy-doped p-region 550a may form source terminal 221 of state transistor 220, which as described above with reference to FIG. 2, may be coupled to the source line SL. Heavy-doped p-region 550b may be shared by state transistor 220 and access transistor 230. For example, heavy-doped p-region 550b may form both drain terminal 222 of state transistor 220 and source terminal 231 of access transistor 230. Heavy-doped p-region 550c may form drain terminal 232 of access transistor 230, which as described above with reference to FIG. 2 may be coupled to the bit line BL.

After heavy-doped n-region 555 and heavy-doped p-regions 550a, 550b, and 550c are formed, any remaining tunnel oxide over heavy-doped n-region 555 and heavy-doped p-regions 550a, 550b, and 550c, may be removed, for example by etching, to expose the area over heavy-doped n-region 555 and heavy-doped p-regions 550a, 550b, and 550c. A metal film may then be deposited to form silicide 575 over the heavy-doped n-region 555, silicide 576 over heavy-doped p-regions 550a, 550b, and 550c, silicide 577 over shared poly layer 530, and silicide 578 over poly layer 532. Silicide 575, silicide 576, silicide 577, and silicide 578 may help reduce the contact resistance between the respective poly and doped regions and above contacts.

After silicide 575, silicide 576, silicide 577, and silicide 578 are formed, thick oxide 580 may be grown or deposited. Holes may be etched in thick oxide 580 and filled with conductive material to form contacts such as contacts 582 and 584 shown in FIG. 5B.

Contact 582 in FIG. 5B may correspond to contact area 416e shown in FIG. 4, and may couple heavy-doped p-region 550c (which may form drain terminal 232 of access transistor 230) to a conductive metal line 592 coupled to the bit line BL. Contact 584 in FIG. 5B may correspond to contact area 416f shown in FIG. 4, and may couple heavy-doped p-region 550a (which may form source terminal 221 of state transistor 220) to a conductive metal line 594 coupled to the source line SL.

Further, although not shown in the cross-section slices of FIGS. 5A and 5B, further contacts corresponding to contact areas 416a, 416b, 416c, and 416d described above with reference to FIG. 4 may be formed to couple or help couple first n-well 506 (which may form control terminal 214 of control gate 210) to the control line CL, second n-well 508 (which may form body terminals 224 and 234 of state transistor 220 and access transistor 230 respectively) to the n-well line NW, and poly layer 532 (which may form gate terminal 233 of access transistor 230) to the access line AL.

Referring back to FIG. 4, boundary 401 illustrates the boundary lines of an NVM bit cell, such as NVM bit cell 200. Multiple bit cells may be formed side by side and top to bottom in a multi-dimensional array. For example, an additional bit cell may be repeated to the right by mirroring the features of the illustrated bit cell about the right-most boundary line of boundary 401. Likewise, an additional bit cell may be repeated to the left by mirroring the features of the illustrated bit cell about the left-most boundary line of boundary 401. Similarly, an additional bit cell may be repeated to the top by mirroring the features of the illustrated bit cell about the top-most boundary line of boundary 401. Further, an additional bit cell may be repeated to the bottom by mirroring the features of the illustrated bit cell about the bottom-most boundary line of boundary 401. Such mirroring may be repeated in any direction to generate an NVM bit-cell array, such as NVM bit-cell array 102, of any size suitable for the application of integrated circuit 100.

Given the mirrored and repeated arrangement, different instances of NVM bit cell 200 may share a common first n-well 506 and may share a common second n-well 508 with each other. Moreover, certain lines, such as the access line AL, the control line CL, the source line SL, the bit line BL, and the n-well line NW may be shared by multiple instances of NVM bit cell 200 on either the same row or same column. Thus, as described below with reference to FIG. 6, various controls may be applied to an instance of NVM bit cell 200 not only to erase, write, and read that particular instance of NVM bit cell 200, but also to inhibit that instance from changing state when other bit cells in the same row or column may undergo erase or write operations.

FIG. 6 is a chart illustrating operating conditions of NVM bit cell 200 in accordance with embodiments of the present disclosure.

In some embodiments, each instance of NVM bit cell 200 included in a row of bit cells may be erased together. When the row in which an instance of NVM bit cell 200 is not selected for an erase operation, each of the bit line BL, access line AL, control line CL, source line SL, and n-well line NW may be set to high impedance, as represented by “Z” in FIG. 6. And when the row in which an instance of NVM bit cell 200 is selected for an erase operation, the bit line BL, access line AL, and source line SL, may all be set to high impedance, while a program voltage VPP may be applied to the control line CL and a nominal voltage, of for example, 0 volts may be applied to the n-well line NW. The program voltage VPP applied to the control line may be any suitable voltage, higher than the nominal voltage applied to the n-well line NW, to induce Fowler-Nordheim tunneling as described above with reference to FIG. 3.

With respect to write operations, when both the row and column in which an instance of NVM bit cell 200 are not selected for an write operation, each of the bit line BL, access line AL, control line CL, source line SL, and n-well line NW may be set to high impedance, as represented by “Z” in FIG. 6. By contrast, when the row and column of an instance of NVM bit cell 200 is selected for a write operation, the bit line BL, access line AL, and source line SL, may all be set to high impedance, while a program voltage VPP may be applied to the n-well line NW and a nominal voltage, of for example, 0 volts may be applied to the control line CL. The program voltage VPP applied to the control line may be any suitable voltage, higher than the nominal voltage applied to the n-well line NW, to induce Fowler-Nordheim tunneling as described above with reference to FIG. 3.

When one, but not both, of the row and column of a particular instance of NVM bit cell 200 is selected for a write operation, an inhibit voltage Vinh may be utilized to prevent the particular instance of NVM bit cell 200 from being affected by the write operation of another instance of the bit cell in the same row or column. For example, when the row, but not the column, of the particular instance of NVM bit cell 200 is selected for a write operation, the bit line BL and access line AL may be set to high impedance. Moreover, a nominal voltage, of for example, 0 volts may be applied to the control line and a program voltage VPP may be applied to the n-well line NW as a result of the write operation to another bit cell in the same row. To prevent disturbance to the state of NVM bit cell 200 under such circumstances, an inhibit voltage Vinh may be applied to the source line SL. By applying the inhibit voltage Vinh to the source line SL, which may be connected to the source terminal 221 of state transistor 220, the total voltage potential across the state-transistor tunnel oxide layer and the control-gate tunnel oxide layer may be reduced to a level that limits or inhibits Fowler-Nordheim tunneling. The inhibit voltage Vinh may be any voltage, for example lower than the program voltage VPP, suitable to limit or inhibit Fowler-Nordheim tunneling.

As another example, when the column, but not the row, of a particular instance of NVM bit cell 200 is selected for a write operation, the bit line BL, access line AL, control line CL, and n-well line NW may all be set to high impedance. And to prevent disturbance to the state of NVM bit cell 200 under such circumstances, an inhibit voltage Vinh may be applied to the source line SL.

With respect to read operations, when both the row and column in which an instance of NVM bit cell 200 are not selected for a read operation, each of the bit line BL, access line AL, control line CL, source line SL, and n-well line NW may be set to high impedance, as represented by “Z” in FIG. 6. When the row and column of an instance of NVM bit cell 200 are selected for a read operation, a nominal voltage of zero volts may be applied to the source line SL and the n-well line NW, a negative supply voltage −VDD may be applied to the access line AL, a gate-read voltage VGR may be applied to the control line, and a negative drive voltage −VDR may be applied to the bit line BL, as described above with reference to FIG. 3.

When one, but not both, of the row and column of a particular instance of NVM bit cell 200 is selected for a read operation, certain lines may be set to high impedance to prevent disturbance of the particular instance of NVM bit cell 200. For example, when the row, but not the column, of the particular instance of NVM bit cell 200 is selected for a read operation, a nominal voltage of zero volts may be applied to the n-well line NW, a negative supply voltage −VDD may be applied to the access line AL, and a gate-read voltage VGR may be applied to the control line, as a result of the read operation to a different bit cell in the same row. To prevent disturbance of the state of NVM bit cell 200 under such circumstances, the bit line BL and the source line SL may be set to high impedance.

As another example, when the column, but not the row, or a particular instance of NVM bit cell is selected for a write operation, negative drive voltage −VDR may be applied to bit line BL, a negative supply voltage −VDD may be applied to the access line AL, and a nominal voltage of zero volts may be applied to the source line SL. Under such circumstances, to prevent a false read of another bit cell in the same column sharing the same bit line BL and source line SL, the control line CL and n-well line NW of the particular instance of NVM bit cell 200 may be set to high impedance.

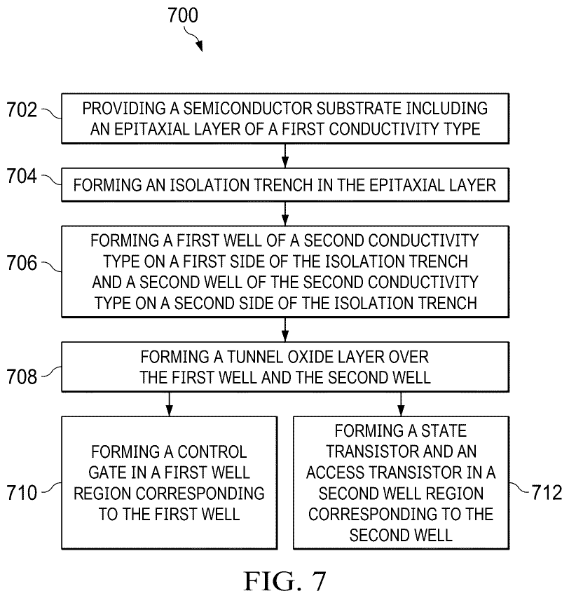

FIG. 7 illustrates method 700 for manufacturing an non-volatile memory (NVM) bit cell, such as NVM bit cell 200, in accordance with embodiments of the present disclosure. Method 700 may be performed by any suitable mechanism. Method 700 may be performed with fewer or more steps than shown in FIG. 7. Moreover, steps of method 700 may be omitted, repeated, performed in parallel, performed in a different order than shown in FIG. 7, or performed recursively. One or more steps of method 700, although shown in an order, may be performed at the same time or in a re-ordered manner.

Step 702 may include providing a semiconductor substrate including an epitaxial layer of a first conductivity type. For example, semiconductor substrate 501 may be provided and may include epitaxial layer 502. In some embodiments, semiconductor substrate 501 may be a p-type conductivity type, and epitaxial layer 502 may be a p-type conductivity type.

Step 704 may include forming an isolation trench in the epitaxial layer. For example, isolation trench 504 may be formed in epitaxial layer 502.

Step 706 may include forming a first well of a second conductivity type on a first side of the isolation trench and a second well of the second conductivity type on a second side of the isolation trench. For example, as described above with reference to FIGS. 4, 5A, and 5B, n-type doping may be applied to epitaxial layer 502 to create a first well, such as first n-well 506, on one side of isolation trench 504 and a second well, such as second n-well 508, on a second side of isolation trench 504. First n-well 506 and second n-well 508 may thus have a second conductivity type, for example n-type conductivity, different from the first conductivity type, for example p-type conductivity, of semiconductor substrate 501 and epitaxial layer 502. In some embodiments, each of the first well and the second well may be formed with a well depth that is lesser than a trench depth of the isolation trench. For example, as shown in FIG. 5A, the well depth of first n-well 506 and second n-well 508 may be lesser than the trench depth of isolation trench 504.

Step 708 may include forming a tunnel oxide layer over the first well and the second well. For example, as shown in FIGS. 5A and 5B, a tunnel oxide layer 520 may be formed, including over first n-well 506 and over second n-well 508.

Step 710 may include forming a control gate in a first well region corresponding to the first well. For example, control gate 210 may be formed in a first n-well region corresponding to first n-well 506. For the purposes of the present disclosure, the area including first n-well 506 and the space above first n-well 506 may be referred to as the first well region or the first n-well region corresponding to first n-well 506.

Step 712 may include forming a state transistor and an access transistor in a second well region corresponding to the second well. For example, state transistor 220 and access transistor 230 may be formed in a second n-well region corresponding to second n-well 508. For the purposes of the present disclosure, the area including second n-well 508 and the space above second n-well 508 may be referred to as the second well region or second n-well region corresponding to second n-well 508.

In some embodiments, the forming of the control gate in step 710 and the forming of the state transistor in step 712 may include providing a shared poly layer to serve as a floating terminal of the control gate and a floating-gate terminal of the state transistor. For example, as described above with reference to FIGS. 5A and 5B, a single layer of poly may be deposited and patterned after tunnel oxide layer 520 is formed. As shown in FIGS. 5A and 5B, the patterned poly may form shared poly layer 530 as well as poly layer 532. Shared poly layer 530 may extend across isolation trench 504 and over first n-well 506 and second n-well 508, and may form both floating terminal 213 of control gate 210 and floating-gate terminal 223 of state transistor 220.

Although certain example embodiments are described herein as forming control gate 210 in a first well region corresponding to first n-well 506, and forming state transistor 220 and access transistor 230 as PMOS transistors in a second well region corresponding to second n-well 508, the components of NVM bit cell 200 may alternatively be formed in well regions corresponding to p-wells. For example, in some embodiments, a first p-well may be formed within first n-well 506, and a second p-well may be formed within second n-well 508. Control gate 210 may thus be formed in a first well region corresponding to the first p-well, with the first p-well forming control terminal 214 of control gate 210. Further, state transistor 220 and access transistor 230 may be implemented as NMOS transistors within the second p-well. In such embodiments, isolation trench 504 may have a trench depth greater than the well depths of both the first and second p-wells as well as first n-well 506 and first p-well 508. Moreover, in such embodiments, the n-well line NW may be alternatively referred to as the p-well line PW due to the implementation of state transistor 220 and access transistor 230 as NMOS transistors within a p-well. For such embodiments, the same principles apply as described above for inducing Fowler-Nordheim tunneling for both the erase operation and the write operation, although different read-operation voltages may be applied (with the bit line BL voltage being higher than the source line SL voltage) to account for the implementation of state transistor 220 and access transistor 230 as NMOS transistors.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

What is claimed is:

1. A non-volatile memory bit cell, comprising:
a first well region;
a second well region;
an isolation trench between the first well region and the second well region, wherein the isolation trench has a trench depth that is greater than a well depth of the first well region and the second well region;
a control gate formed in the first well region;
a state transistor formed in the second well region, the state transistor having a floating-gate terminal coupled to a floating terminal of the control gate; and
an access transistor formed in the second well region and coupled in series with the state transistor.

2. The non-volatile memory bit cell of claim 1, wherein:
the first well region comprises a first n-well; and
the second well region comprises a second n-well.

3. The non-volatile memory bit cell of claim 1, wherein:
the state transistor is a PMOS state transistor; and
the access transistor is a PMOS access transistor.

4. The non-volatile memory bit cell of claim 1, wherein the control gate includes a control-gate tunnel oxide layer.

5. The non-volatile memory bit cell of claim 1, wherein the state transistor includes a state-transistor tunnel oxide layer.

6. The non-volatile memory bit cell of claim 1, wherein the state transistor and the control gate are collectively configured to utilize Fowler-Nordheim tunneling for an erase operation and a write operation.

7. The non-volatile memory bit cell of claim 1, wherein a shared poly layer forms the floating terminal of the control gate and the floating-gate terminal of the state transistor.

8. The non-volatile memory bit cell of claim 7, wherein:
a first region of the shared poly layer forms the floating terminal of the control gate;
a second region of the shared poly layer forms the floating-gate terminal of the state transistor; and
the first region has a first area larger than a second area of the second region.

9. An integrated circuit, comprising:
a logic block; and
a non-volatile memory (NVM) bit-cell array coupled to the logic block, wherein each bit cell of the NVM bit-cell array comprises:
a first well region;
a second well region;
an isolation trench between the first well region and the second well region, wherein the isolation trench has a trench depth that is greater than a well depth of the first well region and the second well region;
a control gate formed in the first well region;
a state transistor formed in the second well region, the state transistor having a floating-gate terminal coupled to a floating terminal of the control gate; and
an access transistor formed in the second well region and coupled in series with the state transistor.

10. The integrated circuit of claim 9, wherein:
the first well region comprises a first n-well; and
the second well region comprises a second n-well.

11. The integrated circuit of claim 9, wherein:
the state transistor is a PMOS state transistor; and
the access transistor is a PMOS access transistor.

12. The integrated circuit of claim 9, wherein the control gate includes a control-gate tunnel oxide layer.

13. The integrated circuit of claim 9, wherein the state transistor includes a state-transistor tunnel oxide layer.

14. The integrated circuit of claim 9, wherein the state transistor and the control gate are collectively configured to utilize Fowler-Nordheim tunneling for an erase operation and a write operation.

15. The integrated circuit of claim 9, wherein a shared poly layer forms the floating terminal of the control gate and the floating-gate terminal of the state transistor.

16. The integrated circuit of claim 15, wherein:
a first region of the shared poly layer forms the floating terminal of the control gate;
a second region of the shared poly layer forms the floating-gate terminal of the state transistor; and
the first region has a first area larger than a second area of the second region.

17. A method, comprising:
providing a semiconductor substrate including an epitaxial layer of a first conductivity type;
forming an isolation trench in the epitaxial layer;
forming a first well of a second conductivity type on a first side of the isolation trench and a second well of the second conductivity type on a second side of the isolation trench;
forming a tunnel oxide layer over the first well and the second well;
forming a control gate in a first well region corresponding to the first well; and
forming a state transistor and an access transistor in a second well region corresponding to the second well.

18. The method of claim 17, wherein each of the first well and the second well are formed with a well depth that is lesser than a trench depth of the isolation trench.

19. The method of claim 17, further comprising providing a shared poly layer to serve as a floating terminal of the control gate and a floating-gate terminal of the state transistor.

20. The method of claim 17, wherein:
a first region of a shared poly layer forms the floating terminal of the control gate;
a second region of the shared poly layer forms the floating-gate terminal of the state transistor; and
the first region has a first area larger than a second area of the second region.
